(19) United States
(12) Patent Application Publication
(10) Pub. No.: US 2026/0031784 A1
(43) Pub. Date: Jan. 29, 2026

(54) PACKAGED MULTI-LAYER PIEZOELECTRIC SUBSTRATE ACOUSTIC WAVE DEVICE WITH INSULATOR FOR REDUCED DC LEAKAGE

(71) Applicant: Skyworks Solutions, Inc., Irvine, CA (US)

(72) Inventors: Rei Goto, Osaka-Shi (JP); Atsushi Takano, Kadoma-Shi (JP)

(21) Appl. No.: 19/256,727

(22) Filed: Jul. 1, 2025

Related U.S. Application Data
(60) Provisional application No. 63/675,047, filed on Jul. 24, 2024.
(60) Provisional application No. 63/675,054, filed on Jul. 24, 2024.

(51) Int. Cl. H03H 9/02; H03H 3/08; H03H 9/05; H03H 9/10

(52) U.S. Cl. CPC H03H 9/02574; H03H 3/08; H03H 9/02937; H03H 9/059; H03H 9/1092

(57) ABSTRACT

A packaged multi-layer piezoelectric substrate acoustic wave device with reduced DC leakage is disclosed. The packaged acoustic wave device can include a multi-layer piezoelectric substrate acoustic wave device and a cap structure. The multi-layer piezoelectric substrate acoustic wave device includes a support substrate, a piezoelectric layer, and an acoustic wave element. The packaged acoustic wave device can include a terminal that can be connected to the acoustic element through an electrical pathway. The terminal can be provided with the multi-layer piezoelectric substrate acoustic wave device or with the cap structure. The packaged acoustic wave device can include an insulator that can prevent or suppress the DC leakage from the electrical pathway. The electrical pathway can include a via formed in the support substrate of the multi-layer piezoelectric substrate, a via formed in a cap substrate of the cap structure, a conductive layer, or a conductive pillar.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/675,047, filed Jul. 24, 2024, titled “PACKAGED MULTI-LAYER PIEZOELECTRIC SUBSTRATE ACOUSTIC WAVE DEVICE,” and U.S. Provisional Patent Application No. 63/675,054, filed Jul. 24, 2024, titled “MULTI-LAYER PIEZOELECTRIC SUBSTRATE ACOUSTIC WAVE DEVICE COUPLED TO CAP STRUCTURE,” are hereby incorporated by reference under 37 CFR 1.57 in their entirety.

### BACKGROUND

### Field

Embodiments of this disclosure relate to packaged multi-layer piezoelectric substrate (MPS) acoustic wave devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a packaged multi-layer piezoelectric substrate acoustic wave device including: a multi-layer piezoelectric substrate including a piezoelectric layer, a support substrate, a conductive via extending at least partially through the support substrate, and a terminal in electrical communication with the conductive via; a cap structure coupled to the multi-layer piezoelectric substrate; an acoustic wave element positioned between the multi-layer piezoelectric substrate and the cap structure, the acoustic element electrically connected to the terminal through an electrical pathway including the conductive via; and an insulator at least partially between the support substrate and the electrical pathway.

In some embodiments, the techniques described herein relate to a packaged device wherein the insulator is disposed along a sidewall of the conductive via.

In some embodiments, the techniques described herein relate to a packaged device wherein the electrical pathway further includes a conductive layer that connects the acoustic wave element and the conductive via.

In some embodiments, the techniques described herein relate to a packaged device wherein a portion of the insulator is positioned between the conductive layer and a surface of the support substrate.

In some embodiments, the techniques described herein relate to a packaged device wherein the insulator is disposed at least partially between the terminal and the support substrate.

In some embodiments, the techniques described herein relate to a packaged device wherein the multi-layer piezoelectric substrate and the cap structure are coupled by way of pillars.

In some embodiments, the techniques described herein relate to a packaged device wherein the pillars include a conductive pillar in electrical connection with the conductive via.

In some embodiments, the techniques described herein relate to a packaged device wherein the insulator includes a cap insulating layer disposed on a surface of the cap structure facing the multi-layer piezoelectric substrate.

In some embodiments, the techniques described herein relate to a packaged device further includes a seal ring hermetically encasing the acoustic wave element.

In some embodiments, the techniques described herein relate to a packaged device wherein the seal ring extends between the cap structure and the piezoelectric layer of the multi-layer piezoelectric substrate.

In some embodiments, the techniques described herein relate to a packaged device wherein the piezoelectric layer extends at least between the acoustic wave element and the conductive via.

In some embodiments, the techniques described herein relate to a packaged device wherein the cap structure includes dielectric material and a coefficient of thermal expansion of the cap structure is within 5% of a coefficient of thermal expansion of the support substrate.

In some embodiments, the techniques described herein relate to a packaged device wherein the insulator includes an oxide layer or a nitride layer.

In some embodiments, the techniques described herein relate to a packaged device wherein the insulator includes a silicon oxide layer and a polycrystalline silicon layer.

In some aspects, the techniques described herein relate to a packaged multi-layer piezoelectric substrate acoustic wave device including: a multi-layer piezoelectric substrate including a piezoelectric layer, a support substrate, a conductive via extending at least partially through the support substrate, and a terminal in electrical communication with the conductive via; a dielectric cap structure coupled to the multi-layer piezoelectric substrate by way of a conductive pillar; and an acoustic wave element positioned between the multi-layer piezoelectric substrate and the cap structure, the acoustic element electrically connected to the terminal through an electrical pathway including the conductive via and the conductive pillar.

In some embodiments, the techniques described herein relate to a packaged device further including an insulator at least partially between the support substrate and the electrical pathway.

In some embodiments, the techniques described herein relate to a packaged device wherein the dielectric cap includes glass.

In some aspects, the techniques described herein relate to a method of forming a packaged multi-layer piezoelectric substrate acoustic wave device, the method including: providing a multi-layer piezoelectric substrate including a piezoelectric layer, a support substrate, a conductive via extending at least partially through the support substrate, and a terminal in electrical communication with the conductive via; electrically connecting an acoustic wave element to the terminal through an electrical pathway including the conductive via; coupling a cap structure to the multi-layer piezoelectric substrate so as to position the acoustic wave element between the multi-layer piezoelectric substrate and the cap structure; and providing an insulator at least partially between the support substrate and the electrical pathway.

In some embodiments, the techniques described herein relate to a method wherein the insulator includes a device side insulator and a cap side insulator.

In some embodiments, the techniques described herein relate to a method wherein the insulator is provided prior to coupling the cap structure and the multi-layer piezoelectric substrate, and the device side insulator and the cap side insulator are provided separately.

In some aspects, the techniques described herein relate to a packaged multi-layer piezoelectric substrate acoustic wave device including: a multi-layer piezoelectric substrate including a piezoelectric layer and a support substrate; a cap structure coupled to the multi-layer piezoelectric substrate, the cap structure including a cap substrate, a conductive via extending at least partially through the cap substrate, and a terminal in electrical communication with the conductive via; an acoustic wave element positioned between the multi-layer piezoelectric substrate and the cap structure, the acoustic element electrically connected to the terminal through an electrical pathway including the conductive via; and an insulator at least partially between the cap substrate and the electrical pathway.

In some embodiments, the techniques described herein relate to a packaged device wherein the insulator is disposed along a sidewall of the conductive via.

In some embodiments, the techniques described herein relate to a packaged device wherein the insulator is disposed at least partially between the terminal and the cap substrate.

In some embodiments, the techniques described herein relate to a packaged device wherein the electrical pathway includes a pillar that extends between the multi-layer piezoelectric substrate and the cap structure.

In some embodiments, the techniques described herein relate to a packaged device wherein the electrical pathway further includes a conductive layer that connects the acoustic wave element and the pillar.

In some embodiments, the techniques described herein relate to a packaged device wherein a portion of the insulator is positioned between the conductive layer and a surface of the support substrate.

In some embodiments, the techniques described herein relate to a packaged device wherein the insulator includes an insulating layer disposed on a surface of the cap structure facing the multi-layer piezoelectric substrate.

In some embodiments, the techniques described herein relate to a packaged device further includes a seal ring hermetically encasing the acoustic wave element.

In some embodiments, the techniques described herein relate to a packaged device wherein the seal ring extends between the cap structure and the piezoelectric layer of the multi-layer piezoelectric substrate.

In some embodiments, the techniques described herein relate to a packaged device wherein the piezoelectric layer extends at least between the acoustic wave element and the conductive via.

In some embodiments, the techniques described herein relate to a packaged device wherein the cap substrate includes dielectric material and a coefficient of thermal expansion of the cap structure is within 5% of a coefficient of thermal expansion of the support substrate.

In some embodiments, the techniques described herein relate to a packaged device wherein the cap substrate is a glass substrate.

In some embodiments, the techniques described herein relate to a packaged device wherein the insulator includes an oxide layer or a nitride layer.

In some embodiments, the techniques described herein relate to a packaged device wherein the insulator includes a silicon oxide layer and a polycrystalline silicon layer.

In some aspects, the techniques described herein relate to a packaged multi-layer piezoelectric substrate acoustic wave device including: a multi-layer piezoelectric substrate including a piezoelectric layer and a support substrate; a cap structure coupled to the multi-layer piezoelectric substrate by way of a conductive pillar, the cap structure including a dielectric cap substrate, a conductive via extending at least partially through the dielectric cap substrate, and a terminal in electrical communication with the conductive via; and an acoustic wave element positioned between the multi-layer piezoelectric substrate and the cap structure, the acoustic element electrically connected to the terminal through an electrical pathway including the conductive via and the conductive pillar.

In some embodiments, the techniques described herein relate to a packaged device further including a dummy pillar extending between the multi-layer piezoelectric substrate and the cap structure.

In some embodiments, the techniques described herein relate to a packaged device wherein the dielectric cap substrate is a glass substrate.

In some aspects, the techniques described herein relate to a method of forming a packaged multi-layer piezoelectric substrate acoustic wave device, the method including: providing a multi-layer piezoelectric substrate including a piezoelectric layer and a support substrate; providing an acoustic wave element to the multi-layer piezoelectric substrate; coupling a cap structure to the multi-layer piezoelectric substrate so as to position the acoustic wave element between the multi-layer piezoelectric substrate and the cap structure, the cap structure including a cap substrate, a conductive via extending at least partially through the cap substrate, and a terminal in electrical communication with the conductive via, the acoustic wave element electrically coupled to the terminal through an electrical pathway including the conductive via; and providing an insulator at least partially between the cap structure and the electrical pathway.

In some embodiments, the techniques described herein relate to a method wherein the insulator includes a device side insulator and a cap side insulator.

In some embodiments, the techniques described herein relate to a method wherein the insulator is provided prior to coupling the cap structure and the multi-layer piezoelectric substrate, and the device side insulator and the cap side insulator are provided separately.

### BRIEF DESCRIPTION OF THE DRAWINGS

Embodiments of this disclosure will now be described, by way of non-limiting example, with reference to the accompanying drawings.

FIGS. 1-4 are schematic cross-sectional side views of various packaged acoustic wave devices that include a conductive via on a device side, according to embodiments.

FIGS. 5-7 are schematic cross-sectional side views of various packaged acoustic wave devices that include a conductive via on a cap side, according to embodiments.

FIG. 8A is a schematic diagram of a transmit filter that includes a surface acoustic wave resonator according to an embodiment.

FIG. 8B is a schematic diagram of a receive filter that includes a surface acoustic wave resonator according to an embodiment.

FIG. 9 is a schematic diagram of a radio frequency module that includes a surface acoustic wave resonator according to an embodiment.

FIG. 10 is a schematic diagram of a radio frequency module that includes filters with surface acoustic wave resonators according to an embodiment.

FIG. 11 is a schematic block diagram of a module that includes an antenna switch and duplexers that include a surface acoustic wave resonator according to an embodiment.

FIG. 12A is a schematic block diagram of a module that includes a power amplifier, a radio frequency switch, and duplexers that include a surface acoustic wave resonator according to an embodiment.

FIG. 12B is a schematic block diagram of a module that includes filters, a radio frequency switch, and a low noise amplifier according to an embodiment.

FIG. 13A is a schematic block diagram of a wireless communication device that includes a filter with a surface acoustic wave resonator in accordance with one or more embodiments.

FIG. 13B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with, for example, surface acoustic wave (SAW) devices and/or bulk acoustic wave (BAW) devices. Certain SAW devices may be referred to as SAW resonators and certain BAW devices can be referred to as BAW resonators. Any features of the SAW resonators discussed herein can be implemented in any suitable SAW device such as a multi-layer piezoelectric substrate (MPS) SAW device.

A multi-layer piezoelectric substrate (MPS) acoustic wave device, such as a multi-layer piezoelectric substrate surface acoustic wave (MPS-SAW) device can include a support substrate, a piezoelectric layer over the support substrate, and an interdigital transducer (IDT) electrode in electrical communication with the piezoelectric layer. The thermal dissipation ability of the MPS-SAW device is generally greater than other types of SAW devices, such as a temperature compensated (TC) SAW device that includes a temperature compensation layer over the IDT electrode.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors. Also, high power durability can be a significant aspect for enabling reliable SAW devices. Further, high temperature cycle reliability can be a significant aspect for enabling mass production of SAW devices.

An acoustic wave device (e.g., a SAW device) can be packaged as a packaged acoustic wave device (e.g., a packaged SAW device). The acoustic wave device can be an MPS acoustic wave device that includes an MPS and an acoustic wave element. The packaged acoustic wave device includes the acoustic wave device and a packaging structure, such as a cap structure, coupled to the acoustic wave device. The packaged acoustic wave device includes an electrical pathway between the acoustic wave element and a terminal provided as part of the acoustic wave device. When the electrical current travels through the electrical pathway, direct current (DC) leakage can occur, which can degrade the device performance. The DC leakage can be electrical current leakage through, for example, the MPS and/or the cap structure.

A low noise amplifier (LNA) can be implemented in an acoustic wave system, such as a receive (RX) filter, to amplify a relatively weak signal received by an antenna. A bias voltage can be applied to the LNA to set the operating point of its active components thereby providing the amplification. However, when the DC leakage occurs in the acoustic wave device, desired amplification may not be provided, which can lead to degradation of receive sensitivity.

Various embodiments disclosed herein relate to packaged multi-layer piezoelectric substrate (MPS) acoustic wave devices (e.g., packaged MPS-SAW devices) with reduced DC leakage. A packaged MPS acoustic device according to some embodiments disclosed herein can include an MPS acoustic wave device and a cap structure coupled to the MPS acoustic wave device. The MPS acoustic wave device includes a support substrate, a piezoelectric layer, and an acoustic wave element. For example, the acoustic wave element can be a SAW element and include an interdigital transducer electrode in electrical communication with the piezoelectric layer. The packaged MPS acoustic wave device can include a terminal that can be connected to the acoustic element through an electrical pathway. The terminal can be provided with the MPS acoustic wave device or with the cap structure. The packaged MPS acoustic wave device can include an insulator that can prevent or suppress the DC leakage from the electrical pathway. For example, the electrical pathway can include a via formed in the support substrate of the MPS, a via formed in a cap substrate of the cap structure, a conductive layer, or a conductive pillar. In some embodiments, the cap substrate can be a dielectric substrate, such as a glass substrate. One or more features that can prevent or suppress the DC leakage can be referred to as a DC leakage barrier or suppression structure.

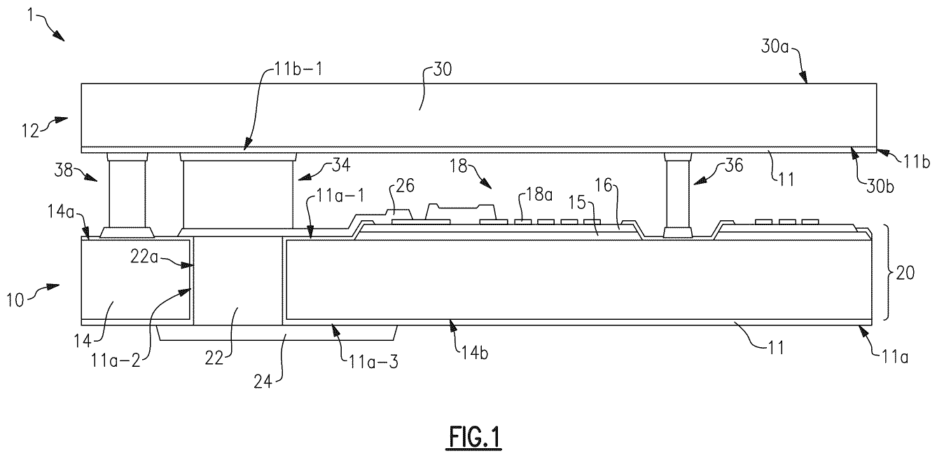

FIG. 1 is a schematic cross-sectional side view of a portion of a packaged multi-layer piezoelectric substrate (MPS) surface acoustic wave (SAW) device 1 according to an embodiment. The packaged MPS-SAW device 1 is an example of an MPS acoustic wave device. The packaged MPS-SAW device 1 can include an MPS-SAW device 10, an insulator 11, and a packaging structure (e.g., a cap structure 12). In some embodiments, the insulator 11 can include one or more insulating layers and/or one or more portions of an insulating layer. The insulator 11 can also be referred to as an insulation structure or a DC leakage barrier structure.

The MPS-SAW device 10 can include a support substrate 14 having a first side 14a and a second side 14b, a functional layer 15 over the first side 14a of the support substrate 14, a piezoelectric layer 16 over the functional layer 15, and one or more acoustic wave elements 18. The one or more acoustic wave elements 18 can include a SAW resonator and have an interdigital transducer electrode 18a. The interdigital transducer electrode 18a can be in electrical communication with the piezoelectric layer 16. The support substrate 14, the functional layer 15, and the piezoelectric layer 16 can together define an MPS 20.

The MPS-SAW device 10 can also include a conductive via 22 that extends at least partially (e.g., fully) through a thickness of the support substrate 14 between the first side 14a and the second side 14b, a terminal 24 on the second side 14b of the support substrate 14, and a conductive layer 26 electrically connecting the acoustic wave element 18 and the conductive via 22. The conductive layer 26 and the conductive via 22 can provide an electrical pathway between the acoustic wave element 18 and the terminal 24. Although only one terminal 24 is illustrated in FIG. 1, there may be a plurality of terminals provided in the packaged MPS-SAW device 1. In some embodiments, the plurality of terminals can include signal terminals and ground terminals.

The cap structure 12 can include a cap substrate 30 having a first side 30a and a second side 30b opposite the first side 30a. The second side 30b can face the MPS-SAW device 10. The cap substrate 30 can also be referred to as a cap wafer in some applications. The one or more acoustic wave elements 18 can be positioned between the MPS-SAW device 10 and the cap structure 12. The MPS-SAW device 10 and the cap structure 12 can be coupled by a pillar 34 (e.g., a conductive pillar), a dummy pillar 36, and a seal ring 38. In some embodiments, the electrical pathway can include the pillar 34. A width of the via 22 can be narrower than a width of the pillar 34. Each of the pillar 34, the dummy pillar 36, and the seal ring 38 may include a sputter layer.

The insulator 11 can be provided at least partially between the electrical pathway and the support substrate 14 and/or the cap substrate 30. The insulator 11 can include a device side insulator 11a and a cap side insulator 11b. The device side insulator 11a can include a portion 11a-1 that is positioned at least partially between the support substrate 14 and the conductive layer 26, a portion 11a-2 positioned between a sidewall 22a of the conductive via 22 and the support substrate 14, and a portion 11a-3 between the support substrate 14 and the terminal 24. The cap side insulator 11b can include a portion 11b-1 positioned between the pillar 34 and the cap substrate 30.

The portion 11a-1 of the insulator 11 can prevent or mitigate DC leakage from the conductive layer 26 to the support substrate 14. The portion 11a-2 of the insulator 11 can prevent or mitigate DC leakage from the conductive via 22 to the support substrate 14. The portion 11a-3 of the insulator 11 can prevent or mitigate DC leakage from the terminal 24 to the support substrate 14. The portion 11b-1 of the insulator 11 can prevent or mitigate DC leakage from the pillar 34 to the cap substrate 30.

The insulator 11 can include any suitable dielectric material. In some embodiments, different portions of the insulator 11 can be formed with different materials and/or in different processes. For example, the device side insulator 11a can include a first material and the cap side insulator 11b can include a second material. The first material for the device side insulator 11a can include, for example, silicon oxide (e.g., silicon dioxide (SiO₂)) and the second material for the cap side insulator 11b can include, for example, polycrystalline silicon. In some embodiments, materials of the insulator 11 can include silicon oxide, silicon nitride, aluminum nitride, or silicon oxynitride.

A method of forming the packaged MPS-SAW device 1 can include providing the acoustic wave element 18 on the first side 14a of the support substrate 14, forming the portion 11a-1 of the insulator 11, and forming the conductive layer 26. The method can also include providing the cap side insulator 11b including the portion 11b-1 to the cap substrate 30, and coupling the MPS-SAW device 10 to the cap structure 12 by, for example, the pillar 34, the dummy pillar 36, and the seal ring 38. Providing the cap side insulator 11b can include providing an insulating layer (e.g., a polycrystalline silicon layer) on the second side 30b of the cap substrate 30. The method can also include removing (e.g., etching) a portion of the support substrate 14 to form a cavity for the conductive via 22, providing the portions 11a-2, 11a-3 of the insulator 11, filling the cavity with a conductive material to form the conductive via 22, and forming the terminal 24.

Providing the portions 11a-2, 11a-3 of the insulator 11 can include providing an insulating layer (e.g., a SiO₂ layer) by way of deposition, such as chemical vapor deposition, on surfaces of the cavity formed in the support substrate 14, the second side 14b of the support substrate 14, and a portion of the conductive layer 26 exposed to the cavity. The insulating layer provided on the portion of the conductive layer 26 exposed to the cavity can be removed by way of, for example, etching (e.g., dry etching). When the insulating layer is provided, a thickness of the insulating layer on the second side 14b of the support substrate 14 can be greater than a thickness of the insulating layer on the conductive layer 26. Therefore, the removing process can expose the conductive layer 26 without completely removing the insulating layer from the second side 14b of the support substrate 14.

A thickness of the portion 11a-1 can be, for example, in a range between 0.05 micrometers and 0.2 micrometers, 0.05 micrometers and 0.1 micrometer, or 0.1 micrometer and 0.15 micrometers. A thickness of the portion 11a-2 can be, for example, in a range between 0.2 micrometers and 0.4 micrometers, 0.2 micrometers and 0.3 micrometers, or 0.3 micrometers and 0.4 micrometers. A thickness of the portion 11a-3 can be, for example, in a range between 0.3 micrometers and 0.7 micrometers, 0.3 micrometers and 0.5 micrometers, or 0.4 micrometers and 0.6 micrometers. A thickness of the cap side insulator 11b including the portion 11b-1 can be, for example, in a range between 0.5 micrometers and 1 micrometer, 0.5 micrometers and 0.8 micrometers, or 0.7 micrometers and 1 micrometer.

In some embodiments, the portion 11a-1 of the insulator 11 can be formed in a front-end process, and the portions 11a-2, 11a-3 of the device side insulator 11a and the cap side insulator 11b can be formed in a back-end process. Having polycrystalline silicon for the cap side insulator 11b can be beneficial when a stealth dicing process is used in a dicing process as it can be easier to weaken polycrystalline silicon by laser than silicon oxide. For example, the dicing process can include a stealth dicing process. The stealth dicing can be conducted from the cap side (e.g., from the first side 30a of the cap substrate 30).

The support substrate 14 can have a relatively high acoustic impedance. For example, the support substrate 14 can have a higher impedance than an impedance of the piezoelectric layer 16 and a higher thermal conductivity than a thermal conductivity of the piezoelectric layer 16. The support substrate 14 can be a silicon substrate, for example. The support substrate 14 can be formed of quartz, spinel, borosilicate, or the like. The support substrate 14 can include a dielectric material. For example, the support substrate 14 can include sapphire or aluminum oxide (Al₂O₃). As compared to some other materials, such as silicon, sapphire has lower or no parasitic surface conductance as sapphire is dielectric. The multi-layer piezoelectric substrate (MPS) that includes a sapphire support substrate can be referred to as a sapphire MPS.

The illustrated MPS-SAW device 10 includes the functional layer 15 between the piezoelectric layer 16 and the support substrate 14. The functional layer 15 can be, for example, a single crystal layer. In some embodiments, the functional layer 15 can be a silicon oxide layer (e.g., a silicon dioxide (SiO₂) layer). In some embodiments, the functional layer 15 can function as an adhesion layer. In some embodiments, a thickness of the functional layer 15 can be the same as, generally similar to, or thinner than the thickness of the piezoelectric layer 16.

The piezoelectric layer 16 can include any suitable piezoelectric layer, such as a lithium based piezoelectric layer. In some embodiments, the piezoelectric layer 16 can be a lithium tantalate (LT) layer. For example, the piezoelectric layer 16 can be an LT layer having a cut angle of 20° (20° Y-cut X-propagation LT) or a cut angle of 60° (60° Y-cut X-propagation LT). For example, the piezoelectric layer 16 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 16. For example, the piezoelectric layer 16 can be an LN layer having a cut angle of about 118° (118° Y-cut X-propagation LN) or more or a cut angle of about 132° (132Y-cut X-propagation LN) or less. For example, the piezoelectric layer 16 can be 125±20° Y-cut LN, 125±15° Y-cut LN, 125±10° Y-cut LN, or 125±5° Y-cut LN. A thickness of the piezoelectric layer 16 can be selected based on a wavelength λ or L of a surface acoustic wave generated by the MPS-SAW device 10 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 16 can be sufficiently thick to avoid significant frequency variation. For example, the thickness of the piezoelectric layer 16 can be in a range of 0.1 L to 0.5, 0.1 L to 0.3 L, or 0.1 L to 0.2 L. Selecting the thickness of the piezoelectric layer 16 from these ranges can be critical in avoiding significant frequency variation and providing sufficient temperature coefficient of frequency for the MPS-SAW device 10. In some embodiments, the piezoelectric layer 16 can include lithium tantalate (LT) and lithium niobate (LN).

The acoustic wave elements 18 including the IDT electrode 18a can include any suitable IDT electrode material. For example, the IDT electrode 18a can include molybdenum (Mo), aluminum (Al), copper (Cu), Magnesium (Mg), titanium (Ti), tungsten (W), the like, or any suitable combination thereof. The IDT electrode 18a can have a multi-layer structure that includes a first layer and a second layer. One of the first layer and the second layer can be more electrically conductive than the other, and the other one can be more durable (e.g., resistive to metal fatigue). In some embodiments, the first layer or the second layer can have a higher mass density and/or higher Young's modulus than the other. The IDT electrode 18a can be formed with (e.g., formed on or at least partially in) the piezoelectric layer 16. The piezoelectric layer 16 and the IDT electrode 18a can be provided in any suitable manner. For example, the piezoelectric layer 16 and the IDT electrode 18a can be provided in sequence. When the interdigital transducer electrode 18a is provided at least partially in the piezoelectric layer 16, the piezoelectric layer 16 can be partially etched and/or provided in a plurality of steps. The one or more acoustic wave elements 18 can include an additional interdigital transducer electrode and/or an interdigital transducer capacitor.

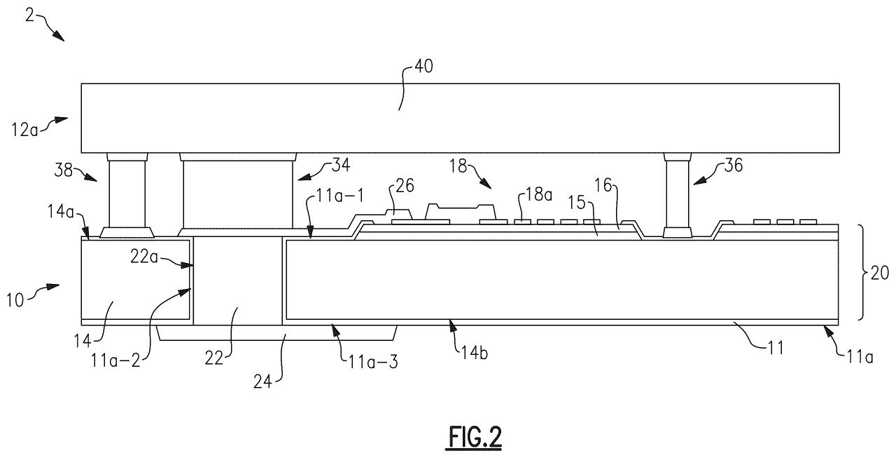

The cap substrate 30 of the cap structure 12 can include any suitable material. In FIG. 1, the cap substrate 30 may include a material that may cause DC leakage without the cap side insulator 11b. However, the material of the cap substrate 30 can include a material that can prevent or mitigate the DC leakage even without the cap side insulator 11b. An example of such embodiments is shown in FIG. 2.

FIG. 2 is a schematic cross-sectional side view of a portion of a packaged multi-layer piezoelectric substrate (MPS) surface acoustic wave (SAW) device 2 according to an embodiment. Unless otherwise noted, the components of the packaged MPS-SAW device 2 shown in FIG. 2 may be structurally and/or functionally the same as or generally similar to like components disclosed herein. The cap structure 12a of the packaged MPS-SAW device 2 can include a dielectric substrate 40 in place of the cap substrate 30.

The dielectric substrate 40 can include a dielectric material that has a coefficient of thermal expansion (CTE) that is similar to a CTE of the support substrate 14. For example, the CTE of the dielectric substrate 40 can be within 1%, within 3%, within 5%, within 8%, within 10%, or within 15% of the CTE of the support substrate 14. In some embodiments, the dielectric substrate 40 can be a glass substrate (e.g., a borosilicate glass substrate). The dielectric substrate 40 can prevent or mitigate DC leakage from the pillar 34 to the cap structure 12a.

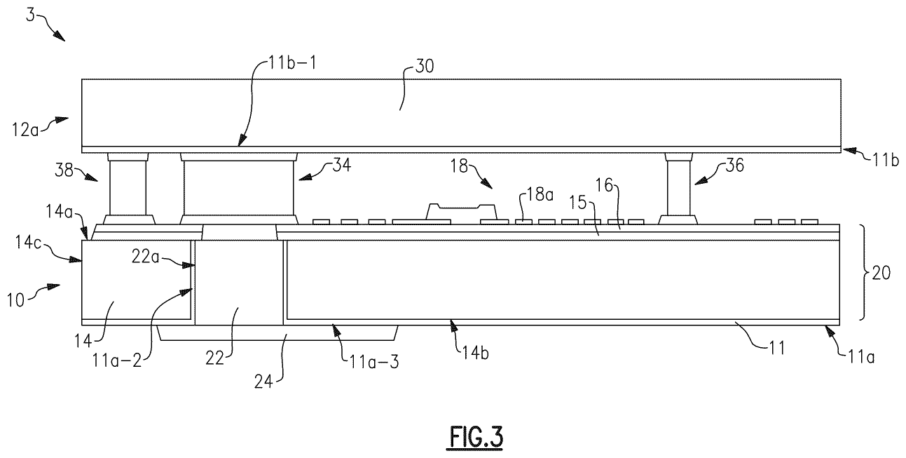

FIG. 3 is a schematic cross-sectional side view of a portion of a packaged multi-layer piezoelectric substrate (MPS) surface acoustic wave (SAW) device 3 according to an embodiment. Unless otherwise noted, the components of the packaged MPS-SAW device 3 shown in FIG. 3 may be structurally and/or functionally the same as or generally similar to like components disclosed herein. The packaged MPS-SAW device 3 can be generally similar to the packaged MPS-SAW device 1 of FIG. 1 except that the functional layer 15 and the piezoelectric layer 16 in the MPS-SAW device 3 extends closer to an edge 14c of the support substrate 14 than the MPS-SAW device 1. The functional layer 15 and/or the piezoelectric layer 16 can extend between the interdigital transducer electrode 18a and the conductive via 22 such that the interdigital transducer electrode 18a and the conductive via 22 are electrically connected without the conductive layer 26 shown in FIGS. 1 and 2. In some embodiments, the functional layer 15 and the piezoelectric layer 16 can also extend to the seal ring 38 or to the edge 14c of the support substrate 14. At least a portion of the functional layer 15 and the piezoelectric layer 16 can be removed (e.g., etched) at or near the edge 14c of the support substrate 14 so as to prevent or mitigate the edge 14c of the support substrate 14 from being damaged (e.g., cracked). The edge 14c of the support substrate 14 can correspond to a dicing line in a dicing process. In some applications, omitting the conductive layer 26 may reduce the lateral size if the packaged MPS-SAW device 3 as compared to similar devices with the conductive layer 26.

FIG. 4 is a schematic cross-sectional side view of a portion of a packaged multi-layer piezoelectric substrate (MPS) surface acoustic wave (SAW) device 4 according to an embodiment. Unless otherwise noted, the components of the packaged MPS-SAW device 4 shown in FIG. 4 may be structurally and/or functionally the same as or generally similar to like components disclosed herein. The packaged MPS-SAW device 4 can be generally similar to the packaged MPS-SAW devices 2 and 3 of FIGS. 2 and 3. The packaged MPS-SAW device 4 includes the cap structure 12a having the dielectric substrate 40 described with respect to FIG. 2, and the functional layer 15 and the piezoelectric layer 16 in the MPS-SAW device 3 extend closer to an edge 14c of the support substrate 14 as described in FIG. 3.

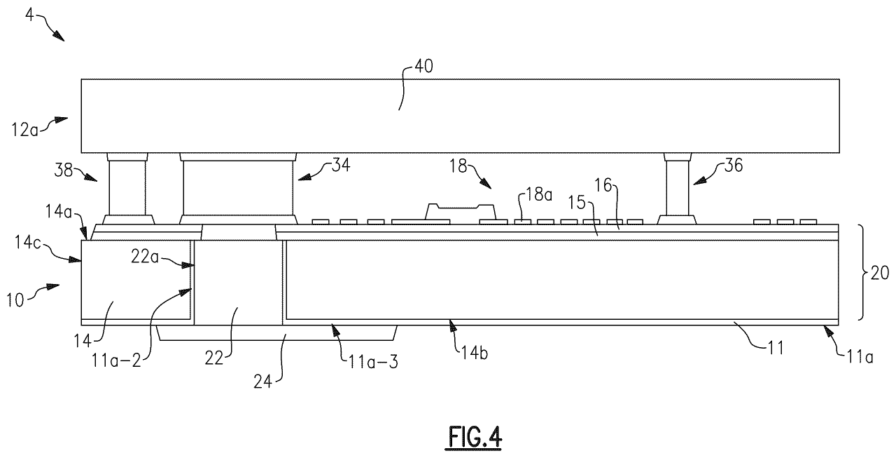

FIGS. 1-4 show embodiments that include a terminal and a through substrate via (the terminal 24 and the conductive via 22) for electrical connection on the device side. However, a terminal can alternatively be provided on the cap side as shown in FIGS. 5-7.

FIG. 5 is a schematic cross-sectional side view of a portion of a packaged multi-layer piezoelectric substrate (MPS) surface acoustic wave (SAW) device 5 according to an embodiment. Unless otherwise noted, the components of the packaged MPS-SAW device 5 shown in FIG. 5 may be structurally and/or functionally the same as or generally similar to like components disclosed herein.

The packaged MPS-SAW device 5 is an example of an MPS acoustic wave device. The packaged MPS-SAW device 5 can include an MPS-SAW device 10a, an insulator 11, and a packaging structure (e.g., a cap structure 12b). The insulator 11 in the packaged MPS-SAW device 5 includes a cap side insulator 11b having portions 11b-1, 11b-2, 11b-3.

The MPS-SAW device 10a can include a support substrate 14 having a first side 14a and a second side 14b, a functional layer 15 over the first side 14a of the support substrate 14, a piezoelectric layer 16 over the functional layer 15, and one or more acoustic wave elements 18. The one or more acoustic wave elements 18 can include a SAW resonator and have an interdigital transducer electrode 18a. The interdigital transducer electrode 18a can be in electrical communication with the piezoelectric layer 16. The support substrate 14, the functional layer 15, and the piezoelectric layer 16 can together define an MPS 20. The conductive via 22, the terminal 24, and the conductive layer 26 shown in FIGS. 1-4 can be omitted in the MPS-SAW device 10a.

The cap structure 12b can include a cap substrate 30 having a first side 30a and a second side 30b opposite the first side 30a. The second side 30b can face the MPS-SAW device 10a. The cap substrate 30 can also be referred to as a cap wafer in some applications. The one or more acoustic wave elements 18 can be positioned between the MPS-SAW device 10a and the cap structure 12b. The MPS-SAW device 10a and the cap structure 12b can be coupled by a pillar 34 (e.g., a conductive pillar), a dummy pillar 36, and a seal ring 38.

The cap structure 12b can also include a conductive via 42 that extends at least partially (e.g., fully) through a thickness of the support substrate cap substrate 30 between the first side 30a and the second side 30b, and a terminal 44 on the first side 40a of the cap substrate 40. The pillar 34 and the conductive via 42 can provide an electrical pathway between the acoustic wave element 18 and the terminal 44. A width of the via 42 can be narrower than a width of the pillar 34. Each of the pillar 34, the dummy pillar 36, and the seal ring 38 may include a sputter layer.

The insulator 11 can be provided at least partially between the electrical pathway and the cap substrate 30. The insulator 11 includes the cap side insulator 11b. The cap side insulator 11b can include a portion 11b-1 positioned between the pillar 34 and the cap substrate 30, a portion 11b-2 positioned between a sidewall 42a of the conductive via 42 and the cap substrate 30, and a portion 11b-3 positioned between the terminal 44 and the cap substrate 30.

The portion 11b-1 of the insulator 11 can prevent or mitigate DC leakage from the pillar 34 to the cap substrate 30. The portion 11b-2 of the insulator 11 can prevent or mitigate DC leakage from the conductive via 42 to the cap substrate 30. The portion 11b-3 of the insulator 11 can prevent or mitigate DC leakage from the terminal 44 to the cap substrate 30.

The insulator 11 can include any suitable dielectric material. In some embodiments, different portions of the cap side insulator 11b can be formed with different materials and/or in different processes. In some embodiments, the cap side insulator 11b can include, for example, silicon oxide (e.g., silicon dioxide (SiO₂)) in at least one portion and polycrystalline silicon in at least another portion.

A method of forming the packaged MPS-SAW device 5 can include providing the acoustic wave element 18 disposed on the first side 14a of the support substrate 14, providing the cap side insulator 11b including the portion 11b-1 to the cap substrate 30, and coupling the MPS-SAW device 10a to the cap structure 12 by, for example, the pillar 34, the dummy pillar 36, and the seal ring 38. Providing the cap side insulator 11b can include providing an insulating layer (e.g., a polycrystalline silicon layer) on the second side 30b of the cap substrate 30. The method can also include removing (e.g., etching) a portion of the cap substrate 30 to form a cavity for the conductive via 42, providing the portions 11b-2, 11b-3 of the insulator 11, filling the cavity with a conductive material to form the conductive via 42, and forming the terminal 44. When a stealth dicing process is used, the stealth dicing can be conducted from the device side (e.g., from the second side 14b of the support substrate 14).

Providing the portions 11b-2, 11b-3 of the insulator 11 can include providing an insulating layer (e.g., a SiO₂ layer) by way of deposition, such as chemical vapor deposition, on surfaces of the cavity formed in the cap substrate 30, the first side 30a of the cap substrate 30, and a portion of the conductive pillar 34 exposed to the cavity. The insulating layer provided on the portion of the conductive pillar 34 exposed to the cavity can be removed by way of, for example, etching (e.g., dry etching). When the insulating layer is provided, a thickness of the insulating layer on the first side 30a of the cap substrate 30 can be greater than a thickness of the insulating layer on the conductive pillar 34. Therefore, the removing process can expose the conductive pillar 34 without completely removing the insulating layer from the first side 30a of the cap substrate 30.

A thickness of the portion 11b-1 can be, for example, in a range between 0.5 micrometers and 1 micrometer, 0.5 micrometers and 0.8 micrometers, or 0.7 micrometers and 1 micrometer. A thickness of the portion 11b-2 can be, for example, in a range between 0.2 micrometers and 0.4 micrometers, 0.2 micrometers and 0.3 micrometers, or 0.3 micrometers and 0.4 micrometers. A thickness of the portion 11b-3 can be, for example, in a range between 0.3 micrometers and 0.7 micrometers, 0.3 micrometers and 0.5 micrometers, or 0.4 micrometers and 0.6 micrometers.

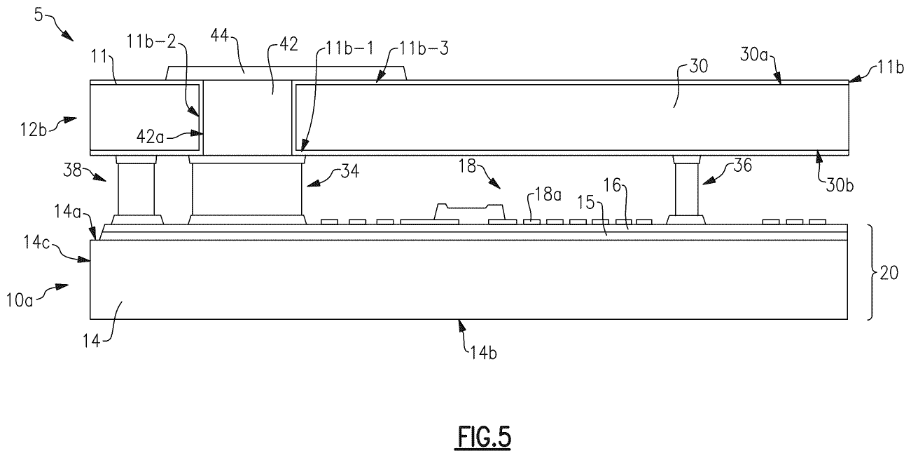

FIG. 6 is a schematic cross-sectional side view of a portion of a packaged multi-layer piezoelectric substrate (MPS) surface acoustic wave (SAW) device 6 according to an embodiment. Unless otherwise noted, the components of the packaged MPS-SAW device 6 shown in FIG. 6 may be structurally and/or functionally the same as or generally similar to like components disclosed herein. The cap structure 12b of the packaged MPS-SAW device 2 can include a dielectric substrate 40 in place of the cap substrate 30.

The dielectric substrate 40 can include a dielectric material that has a coefficient of thermal expansion (CTE) that is similar to a CTE of the support substrate 14. For example, the CTE of the dielectric substrate 40 can be within 1%, within 3%, within 5%, within 8%, within 10%, or within 15% of the CTE of the support substrate 14. In some embodiments, the dielectric substrate 40 can be a glass substrate (e.g., a borosilicate glass substrate). The dielectric substrate 40 can prevent or mitigate DC leakage from the pillar 34 to the cap structure 12b. Because the dielectric substrate 40 can function as an insulator to prevent or suppress the DC leakage from the electrical pathway, the insulator 11 can be omitted in the packaged MPS-SAW device 6. When forming the conductive via 42, a portion of the dielectric substrate 40 can be removed by way of, for example, laser drilling.

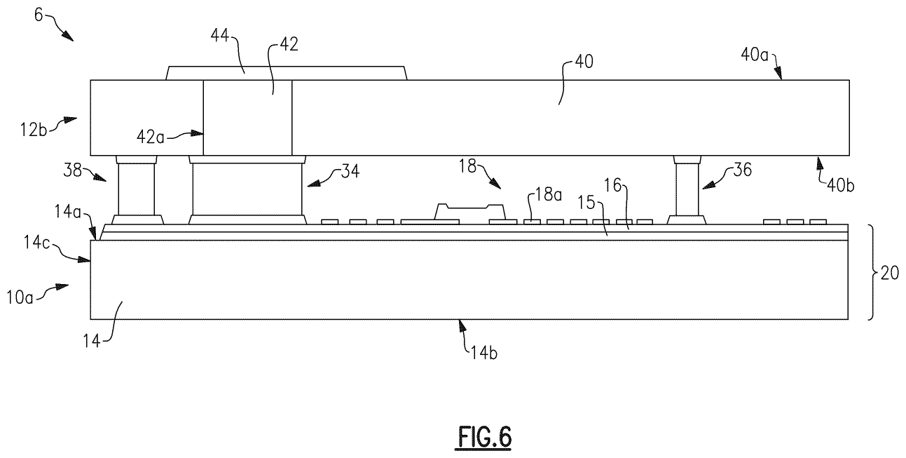

FIG. 7 is a schematic cross-sectional side view of a portion of a packaged multi-layer piezoelectric substrate (MPS) surface acoustic wave (SAW) device 7 according to an embodiment. Unless otherwise noted, the components of the packaged MPS-SAW device 7 shown in FIG. 7 may be structurally and/or functionally the same as or generally similar to like components disclosed herein. The packaged MPS-SAW device 7 can be generally similar to the packaged MPS-SAW device 5 of FIG. 5. In the packaged MPS-SAW device 7, a conductive layer 26 is provided between the pillar 34 and the acoustic wave element 18, and a portion 11a-1 of the insulator 11 is provided between the conductive layer 26 and the support substrate 14.

Although some methods of forming a packaged MPS-SAW device may be described with respect to certain figures, any packaged MPS-SAW device disclosed herein can be formed using suitable processes of the methods disclosed herein. Also, one or more features of different embodiments disclosed herein may be combined or replaced.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more packaged MPS-SAW devices disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

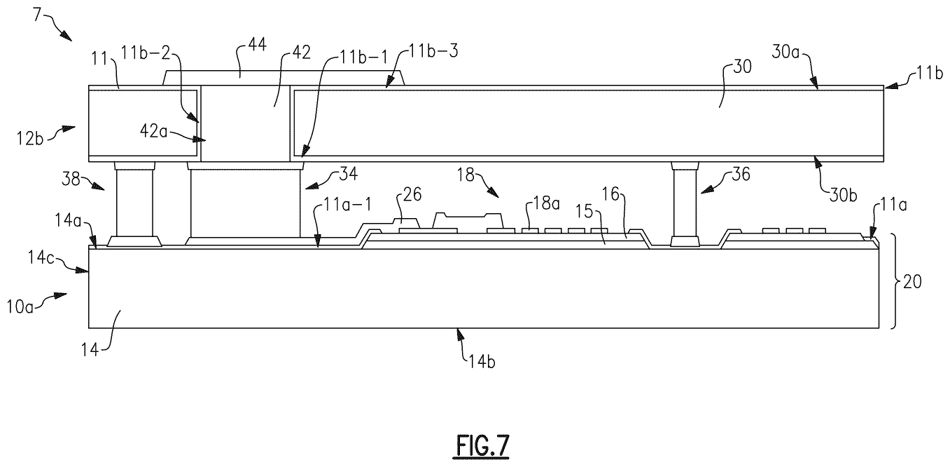

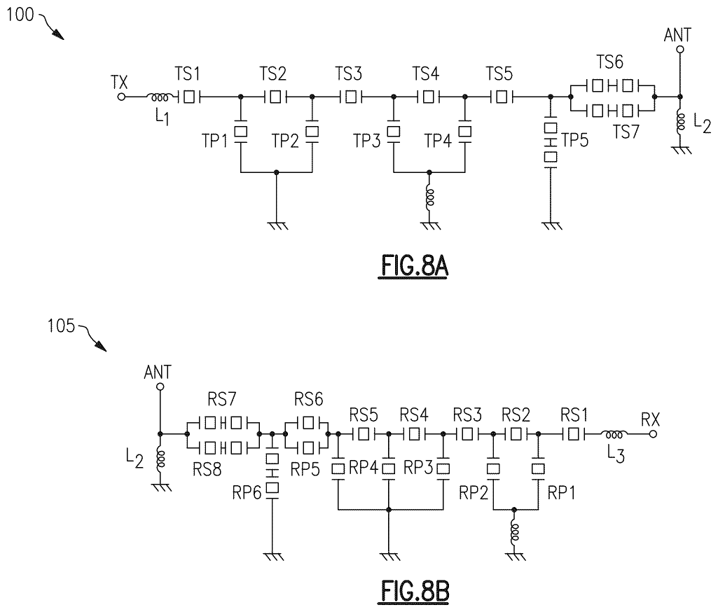

FIG. 8A is a schematic diagram of an example transmit filter 100 that includes surface acoustic wave devices according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be SAW devices in accordance with any suitable principles and advantages disclosed herein. Any suitable number of series SAW resonators and shunt SAW resonators can be included in a transmit filter 100.

FIG. 8B is a schematic diagram of a receive filter 105 that includes surface acoustic wave devices according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. Any suitable number of series SAW resonators and shunt SAW resonators can be included in a receive filter 105.

Although FIGS. 8A and 8B illustrate example ladder filter topologies, any suitable filter topology can include a packaged MPS-SAW device in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

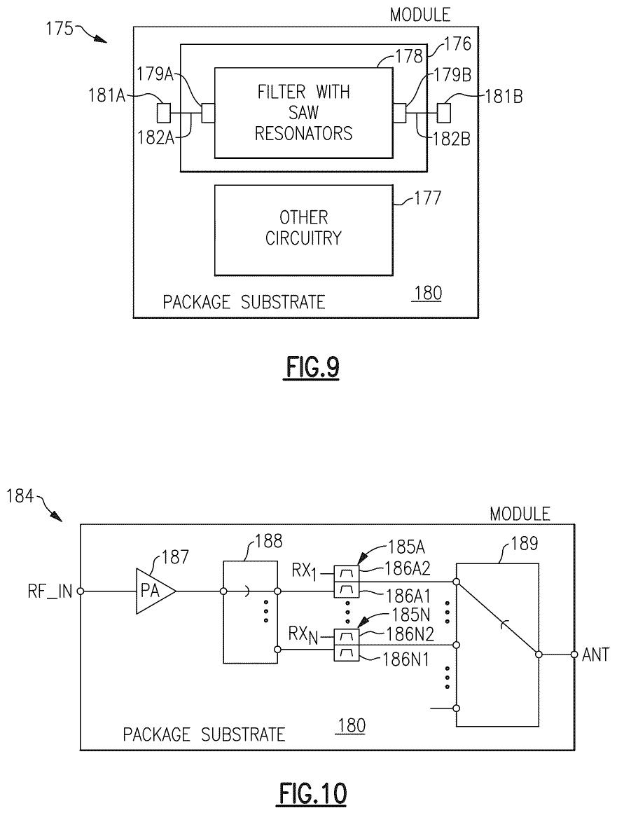

FIG. 9 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 9 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 9. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 10 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 10 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

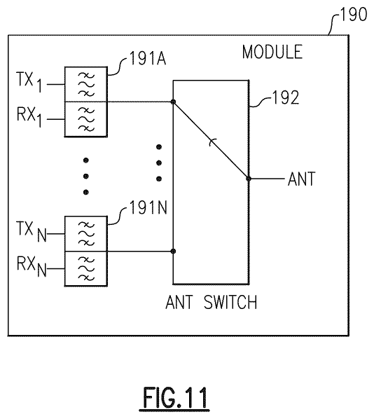

FIG. 11 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

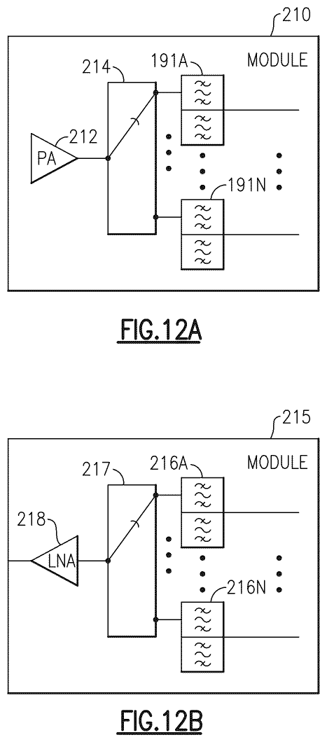

FIG. 12A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 12B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

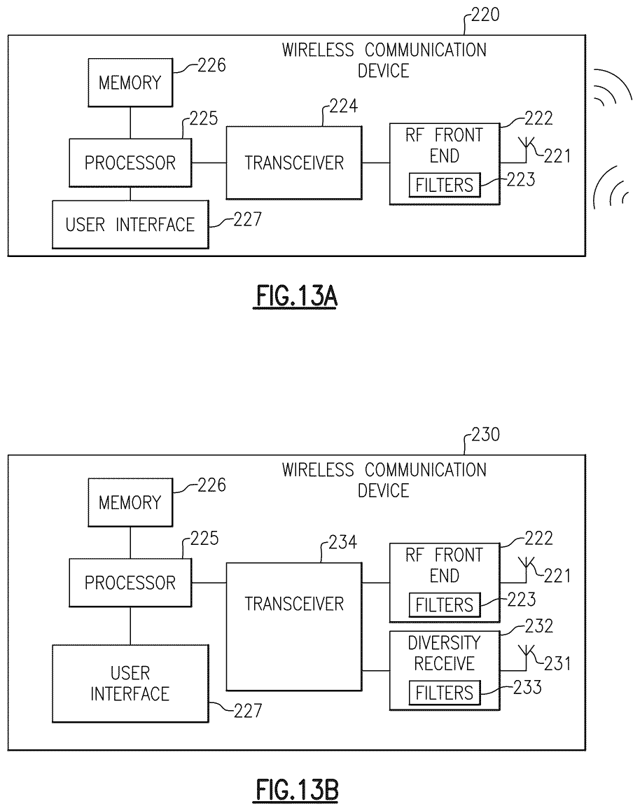

FIG. 13A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 13B is a schematic diagram of a wireless communication device 230 that includes filters 223 in a radio frequency front end 222 and a second filter 233 in a diversity receive module 232. The wireless communication device 230 is like the wireless communication device 220 of FIG. 13A, except that the wireless communication device 230 also includes diversity receive features. As illustrated in FIG. 13B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A packaged multi-layer piezoelectric substrate acoustic wave device comprising:
a multi-layer piezoelectric substrate including a piezoelectric layer, a support substrate, a conductive via extending at least partially through the support substrate, and a terminal in electrical communication with the conductive via;
a cap structure coupled to the multi-layer piezoelectric substrate;
an acoustic wave element positioned between the multi-layer piezoelectric substrate and the cap structure, the acoustic element electrically connected to the terminal through an electrical pathway including the conductive via; and
an insulator at least partially between the support substrate and the electrical pathway.

2. The packaged device of claim 1 wherein the insulator is disposed along a sidewall of the conductive via.

3. The packaged device of claim 1 wherein the electrical pathway further includes a conductive layer that connects the acoustic wave element and the conductive via.

4. The packaged device of claim 3 wherein a portion of the insulator is positioned between the conductive layer and a surface of the support substrate.

5. The packaged device of claim 1 wherein the insulator is disposed at least partially between the terminal and the support substrate.

6. The packaged device of claim 1 wherein the multi-layer piezoelectric substrate and the cap structure are coupled by way of pillars.

7. The packaged device of claim 6 wherein the pillars include a conductive pillar in electrical connection with the conductive via.

8. The packaged device of claim 1 wherein the insulator includes a cap insulating layer disposed on a surface of the cap structure facing the multi-layer piezoelectric substrate.

9. The packaged device of claim 1 further includes a seal ring hermetically encasing the acoustic wave element.

10. The packaged device of claim 9 wherein the seal ring extends between the cap structure and the piezoelectric layer of the multi-layer piezoelectric substrate.

11. The packaged device of claim 1 wherein the piezoelectric layer extends at least between the acoustic wave element and the conductive via.

12. The packaged device of claim 1 wherein the cap structure includes dielectric material and a coefficient of thermal expansion of the cap structure is within 5% of a coefficient of thermal expansion of the support substrate.

13. The packaged device of claim 1 wherein the insulator includes an oxide layer or a nitride layer.

14. The packaged device of claim 1 wherein the insulator includes a silicon oxide layer and a polycrystalline silicon layer.

15. A packaged multi-layer piezoelectric substrate acoustic wave device comprising:
a multi-layer piezoelectric substrate including a piezoelectric layer, a support substrate, a conductive via extending at least partially through the support substrate, and a terminal in electrical communication with the conductive via;
a dielectric cap structure coupled to the multi-layer piezoelectric substrate by way of a conductive pillar; and
an acoustic wave element positioned between the multi-layer piezoelectric substrate and the cap structure, the acoustic element electrically connected to the terminal through an electrical pathway including the conductive via and the conductive pillar.

16. The packaged device of claim 15 further comprising an insulator at least partially between the support substrate and the electrical pathway.

17. The packaged device of claim 15 wherein the dielectric cap includes glass.

18. A method of forming a packaged multi-layer piezoelectric substrate acoustic wave device, the method comprising:
providing a multi-layer piezoelectric substrate including a piezoelectric layer, a support substrate, a conductive via extending at least partially through the support substrate, and a terminal in electrical communication with the conductive via;
electrically connecting an acoustic wave element to the terminal through an electrical pathway including the conductive via;
coupling a cap structure to the multi-layer piezoelectric substrate so as to position the acoustic wave element between the multi-layer piezoelectric substrate and the cap structure; and
providing an insulator at least partially between the support substrate and the electrical pathway.

19. The method of claim 18 wherein the insulator includes a device side insulator and a cap side insulator.

20. The method of claim 19 wherein the insulator is provided prior to coupling the cap structure and the multi-layer piezoelectric substrate, and the device side insulator and the cap side insulator are provided separately.
